(19) United States
(12) Patent Application Publication
(10) Pub. No.: US 2006/0230328 A1
(43) Pub. Date: Oct. 12, 2006

(54) Device and method for recording information

(75) Inventors: Johannis Friso Rendert Blacquiere, Eindhoven (NL); Pope Ijtsma, Eindhoven (NL); Dirk Hamelinck, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/564,911

(22) PCT Filed: Jul. 8, 2004
(86) PCT No.: PCT/IB04/51178

§ 371 Date: Jan. 17, 2006

(30) Foreign Application Priority Data
Jul. 17, 2003 (EP) 03102205.6

(51) Int. Cl. G11C 29/00

(52) U.S. Cl. 714/763

(57) ABSTRACT

A device for recording records information in blocks having logical addresses at a physical address in a track on a record carrier. The logical addresses are translated into the physical addresses in dependence of defect management information, such as primary and secondary defect lists and remapping tables, maintained in defect management areas (61). The defect management information includes assignment information indicative of assignment of physical addresses in parts of the track to user data areas or to defect management areas. The device has assignment means for dynamically adapting the assignment information in dependence of detected defects (54) by assigning an additional physical address range to an additional defect management area (61). The additional physical address range starts near the detected defect (54). Hence the defect (54) is covered by a defect management area, which reduces the need for remapping.

The invention relates to a device for recording information.

The invention further relates to a method of recording of information.

The invention further relates to a computer program product for recording of information.

The invention relates to the field of defect management in recording systems, and in particular to defect management when continuously recording real-time information such as video.

A device and method for recording information on a record carrier are known from U.S. Pat. No. 5,956,309. The apparatus has recording means for recording the information in information blocks having logical addresses on an optical disc in a track at allocated physical addresses. The logical addresses constitute a contiguous storage space. In practice, the record carrier may exhibit defective parts of the track, in particular a defect preventing a block to be recorded at a specific physical address. These defects might be caused by product flaws, scratches, dust, fingerprints, etc. Initially, before any user data is recorded, defects are detected, and physical addresses of defective sectors are removed from use by skipping the affected physical addresses based on a (primary) defect table, a process usually called slipping. In the event of defects detected during use of the record carrier, logical addresses assigned to defective physical addresses are assigned to different physical addresses in a defect management area via a (secondary) defect table, a process usually called remapping or linear replacement. Remapping introduces a performance penalty as remapping introduces a movement of the recording head (for example an optical pickup unit, OPU), and possibly also a medium rotational speed adjustment and rotational delay(s). Hence defect management areas are located distributed over the total recording area to reduce jumping distances. A problem of the known system is that when a series of blocks is to be recorded that has a large continuous range of logical addresses, the corresponding range of physical addresses may extend over one or more defect management areas. Hence during recording and reproducing the continuous range of logical addresses the optical head has to jump across the defect management areas.

It is an object of the invention to provide a system for recording and reproducing information blocks on related physical addresses, while reducing the amount of jumps to remote physical addresses due to defects.

For this purpose in accordance with a first aspect of the invention the device for recording information in blocks having logical addresses comprises recording means for recording marks in a track on a record carrier representing the information, control means for controlling the recording by locating each block at a physical address in the track, the control means comprising addressing means for translating the logical addresses into the physical addresses and vice versa in dependence of defect management information, defect management means for detecting defects and maintaining the defect management information in defect management areas on the record carrier, the defect management information including assignment information indicative of assignment of physical addresses in first parts of the track to at least one user data area, and assignment of physical addresses in second parts of the track to defect management areas, and the defect management information including remapping information indicative for translating a logical address initially mapped to a physical address exhibiting a defect to an alternate physical address in a defect management area, and assignment means for adapting the assignment information in dependence of a detected defect by assigning an additional physical address range to an additional defect management area, the additional physical address range having a starting physical address near the detected defect.

For this purpose in accordance with a second aspect of the invention the method of recording of information in blocks having logical addresses located at a physical address in a track on a record carrier, the logical addresses corresponding to physical addresses in dependence of defect management information, defects being detected and the defect management information being maintained in defect management areas on the record carrier, and the defect management information including assignment information indicative of assignment of physical addresses in first parts of the track to at least one user data area, and assignment of physical addresses in second parts of the track to defect management areas, and the defect management information including remapping information indicative for translating a logical address initially mapped to a physical address exhibiting a defect to an alternate physical address in a defect management area, comprises adapting the assignment information in dependence of a detected defect by assigning an additional physical address range to an additional defect management area, the additional physical address range having a starting physical address near the detected defect.

The measures according to the invention have the effect that the amount and location of defect management areas is adapted to actual defects detected during recording of the record carrier. This has the advantage that defects, once detected, are locally accommodated by either covering the defect itself with a defect management area or providing a defect management area in the vicinity for remapping the defect at a location close to the defective physical address. Hence for local defects only jumps to local defect management areas are required.

The invention is also based on the following recognition. Initial defects on a record carrier may be detected during formatting and may be registered in a primary defect list, which results in skipping the defects, and reassigning all logical addresses following a defect, for example as described in US 2001/0002488. Hence the primary defect list cannot be updated after writing user data because the assignment of logical to physical addresses would change. However scanning a record carrier during formatting is time consuming and therefore often omitted, and defects detected later will be dealt with by remapping. During recording the usual defect management systems heavily rely on remapping defect physical addresses to defect management areas. The inventors have seen that remapping can be avoided or at least reduced by dynamically adapting the assignment information for defect management areas. Hence an area having many defects will be awarded with a lot of defect management areas, whereas a substantially flawless area will have only a minimum of defect management areas. This has the advantage that the storage capacity of the record carrier will not be reduced due to mostly unused defect management areas.

In an embodiment of the device the end portion recording means are for recording the end portion in a defect management area, in particular in a single defect management area. This has the advantage that only a single substantial jump is required for retrieving the series of blocks.

In an embodiment of the device the assignment means are for assigning the additional physical address range including the detected defect. Due to the new assignment of a defect management area having physical addresses covering the defect, the logical address originally mapped to that range are now shifted to a new physical address range. This has the advantage that no remapping is required for the logical address originally corresponding to the physical address having the defect.

In an embodiment of the device the assignment means are for assigning the additional physical address range having a predefined size, or a size based on defect parameters of a preceding or following recording area, in particular the amount and distribution of defect management areas already assigned, the amount of user area between the additional physical address range and a preceding or following defect management area, and/or detected defects. This has the advantage that the size can be easily determined based on the recording format specification. It is noted that the size may be fixed or may depend in a prescribed way on predefined parameters like the radial position, or a selected defect management area distribution scheme. Alternatively the size can be adapted to a distribution of defect management areas already assigned, or to the actual defect situation, such as the filling degree of other defect management areas in the vicinity of the new defect management area.

In an embodiment of the device the assignment means are for assigning the additional physical address range having a size at least including a first detected defect, a second detected defect and the physical addresses between the first and second detected defect. This has the advantage that at least two defect locations are covered by a single defect management area, whereas the intermediate addresses are still available for remapping other defects.

In an embodiment of the device the device comprises contiguous recording detection means for detecting a series of blocks having a continuous logical address range to be recorded in a corresponding allocated physical address range, and the assignment means are for assigning the additional physical address range outside the allocated physical address range. Hence the device detects the type of data that is recorded, and, if continuous, prevents that the new defect management area assigned to the additional physical address range interrupts the allocated physical address range. This has the advantage that the performance of reproducing continuous data is not hampered by jumping across interrupting defect management areas.

Further embodiments are given in the dependent claims.

These and other aspects of the invention will be apparent from and elucidated further with reference to the embodiments described by way of example in the following description and with reference to the accompanying drawings, in which

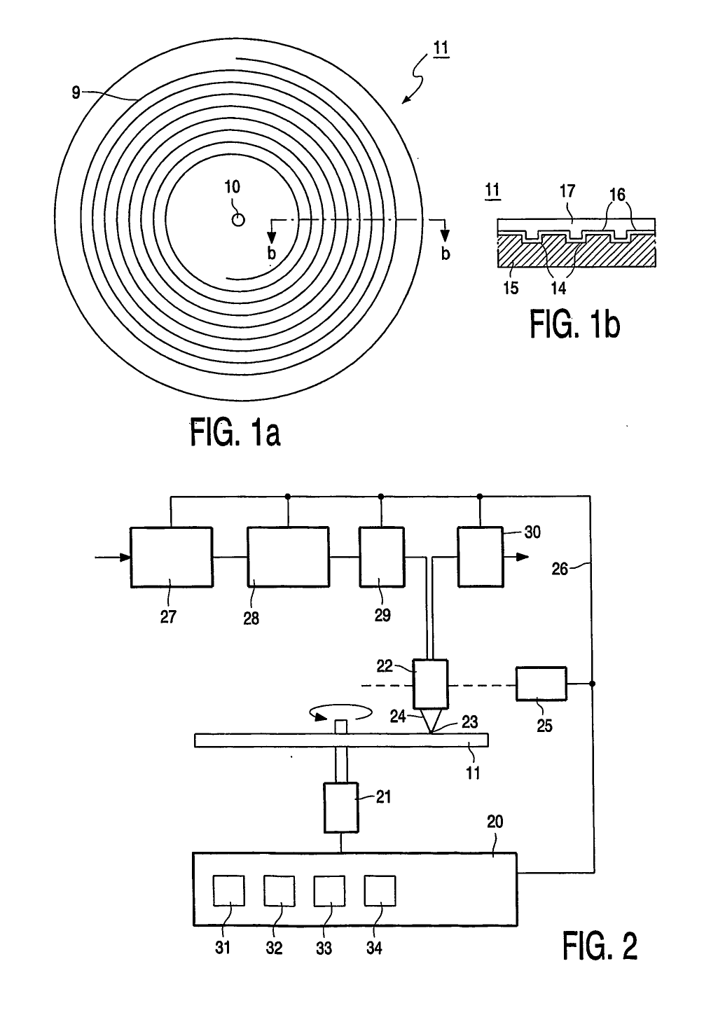

FIG. 1a shows a record carrier (top view),

FIG. 1b shows a record carrier (cross section),

FIG. 2 shows a recording device,

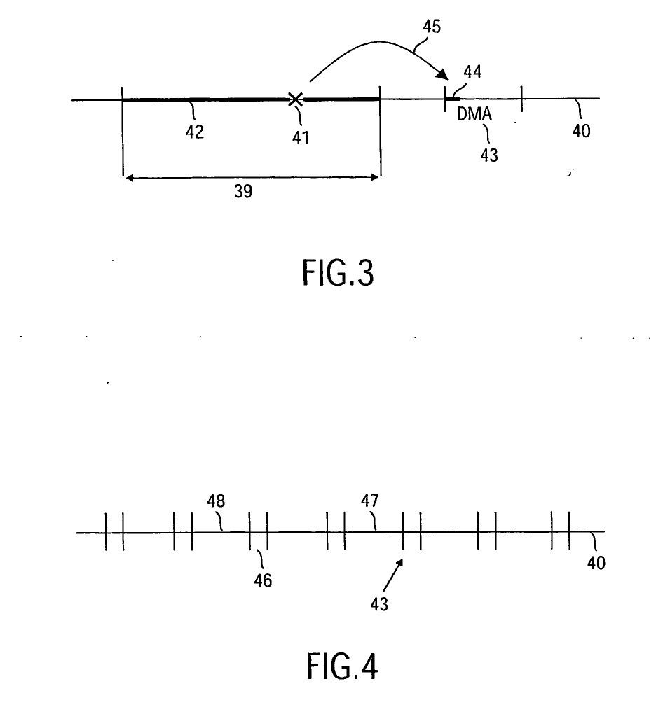

FIG. 3 shows remapping of defective locations,

FIG. 4 shows a defect management layout having distributed defect management areas,

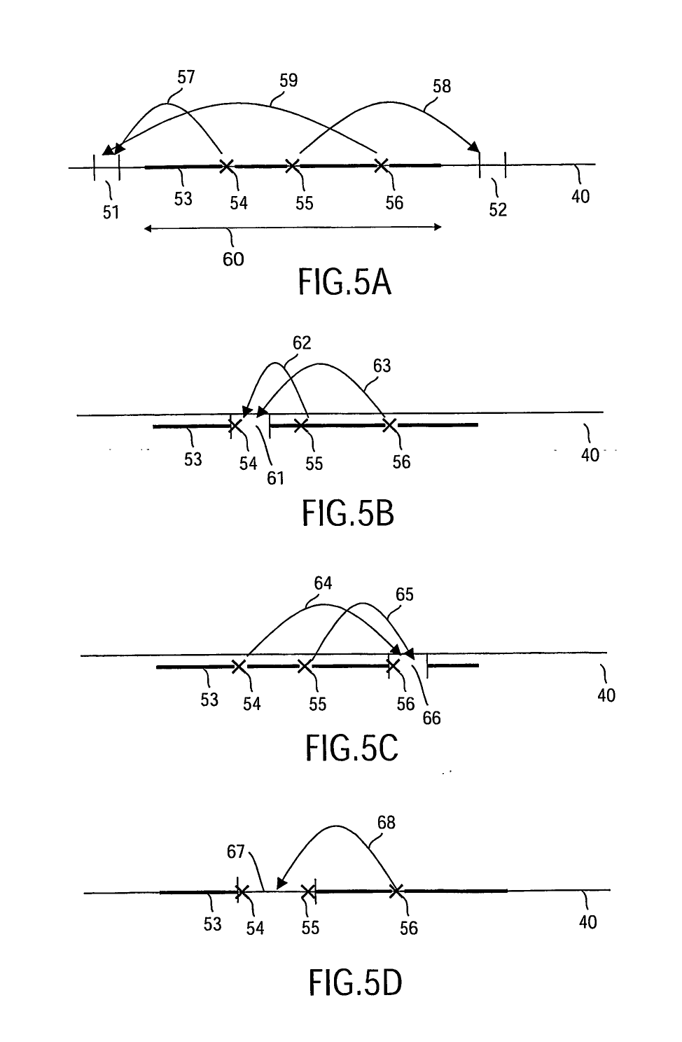

FIG. 5 shows dynamically assigning a defect management area,

FIG. 5A shows a recorded file and remapped logical addresses in a conventional remapping system,

FIG. 5B shows an additionally assigned defect management area,

FIG. 5C shows delayed assignment of a defect management area,

FIG. 5D shows a defect management area assigned covering two defects,

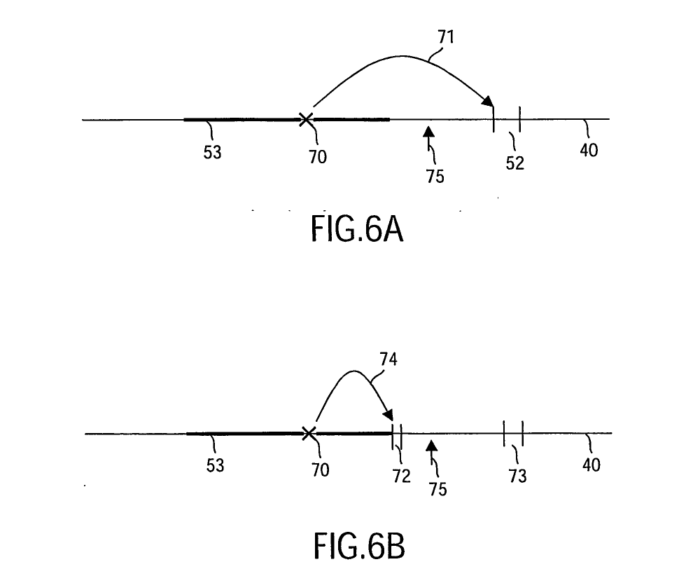

FIG. 6 shows assigning ranges of physical address to a defect management area,

FIG. 6A shows assigned physical addresses and remapped defects in a conventional remapping system, and

FIG. 6B shows assigning an additional physical address range to an additional defect management area.

Corresponding elements in different Figures have identical reference numerals.

FIG. 1a shows a disc-shaped record carrier 11 having a track 9 and a central hole 10. The track 9, being the position of the series of (to be) recorded marks representing information, is arranged in accordance with a spiral pattern of turns constituting substantially parallel tracks on an information layer. The record carrier may be optically readable, called an optical disc, and has an information layer of a recordable type. Examples of a recordable disc are the CD-RW, and rewritable versions of DVD, such as DVD+RW, and the high density writable optical disc using blue lasers, called Blu-ray Disc (BD). Further details about the DVD disc can be found in reference: ECMA-267: 120 mm DVD—Read-Only Disc—(1997). The information is represented on the information layer by recording optically detectable marks along the track, e.g. crystalline or amorphous marks in phase change material. The track 9 on the recordable type of record carrier is indicated by a pre-embossed track structure provided during manufacture of the blank record carrier. The track structure is constituted, for example, by a pregroove 14 in FIG. 1b which enables a read/write head to follow the track during scanning. The track structure comprises position information including so-called physical addresses, for indicating the location of units of information, usually called information blocks. The position information includes specific synchronizing marks for locating the start of such information blocks.

FIG. 1b is a cross-section taken along the line b-b of the record carrier 11 of the recordable type, in which a transparent substrate 15 is provided with a recording layer 16 and a protective layer 17. The protective layer 17 may comprise a further substrate layer, for example as in DVD where the recording layer is at a 0.6 mm substrate and a further substrate of 0.6 mm is bonded to the back side thereof. The pregroove 14 may be implemented as an indentation or an elevation of the substrate 15 material, or as a material property deviating from its surroundings.

The record carrier 11 is intended for carrying digital information in blocks under control of a file management system. The information may include real-time information to be recorded and reproduced continuously, in particular information representing digitally encoded video according to a standardized format like MPEG2.

FIG. 2 shows a recording device for writing information on a record carrier 11 of a type which is writable or re-writable, for example CD-R or CD-RW, or DVD+RW or BD. The device is provided with recording means for scanning the track on the record carrier which means include a drive unit 21 for rotating the record carrier 11, a head 22, a positioning unit 25 for coarsely positioning the head 22 in the radial direction on the track, and a control unit 20. The head 22 comprises an optical system of a known type for generating a radiation beam 24 guided through optical elements focused to a radiation spot 23 on a track of the information layer of the record carrier. The radiation beam 24 is generated by a radiation source, e.g. a laser diode. The head further comprises (not shown) a focusing actuator for moving the focus of the radiation beam 24 along the optical axis of said beam and a tracking actuator for fine positioning the spot 23 in a radial direction on the center of the track. The tracking actuator may comprise coils for radially moving an optical element or may alternatively be arranged for changing the angle of a reflecting element. For writing information the radiation is controlled to create optically detectable marks in the recording layer. The marks may be in any optically readable form, e.g. in the form of areas with a reflection coefficient different from their surroundings, obtained when recording in materials such as dye, alloy or phase change material, or in the form of areas with a direction of magnetization different from their surroundings, obtained when recording in magneto-optical material. For reading the radiation reflected by the information layer is detected by a detector of a usual type, e.g. a four-quadrant diode, in the head 22 for generating a read signal and further detector signals including a tracking error and a focusing error signal for controlling said tracking and focusing actuators. The read signal is processed by read processing unit 30 of a usual type including a demodulator, deformatter and output unit to retrieve the information. Hence retrieving means for reading information include the drive unit 21, the head 22, the positioning unit 25 and the read processing unit 30. The device comprises write processing means for processing the input information to generate a write signal to drive the head 22, which means comprise an (optional) input unit 27, and a formatter 28 and a modulator 29. During the writing operation, marks representing the information are formed on the record carrier. The marks are formed by means of the spot 23 generated on the recording layer via the beam 24 of electromagnetic radiation, usually from a laser diode. Digital data is stored on the record carrier according to a predefined data format. Writing and reading of information for recording on optical disks and formatting, error correcting and channel coding rules are well-known in the art, e.g. from the CD and DVD system.

The control unit 20 is connected via control lines 26, e.g. a system bus, to said input unit 27, formatter 28 and modulator 29, to the read processing unit 30, and to the drive unit 21, and the positioning unit 25. The control unit 20 comprises control circuitry, for example a microprocessor, a program memory and control gates, for performing the procedures and functions according to the invention as described below. The control unit 20 may also be implemented as a state machine in logic circuits.

In an embodiment the recording device is a storage system only, e.g. an optical disc drive for use in a computer. The control unit 20 is arranged to communicate with a processing unit in the host computer system via a standardized interface. Digital data is interfaced to the formatter 28 and the read processing unit 30 directly.

In an embodiment the device is arranged as a stand alone unit, for example a video recording apparatus for consumer use. The control unit 20, or an additional host control unit included in the device, is arranged to be controlled directly by the user, and to perform the functions of the file management system. The device includes application data processing, e.g. audio and/or video processing circuits. User information is presented on the input unit 27, which may comprise compression means for input signals such as analog audio and/or video, or digital uncompressed audio/video. Suitable compression means are for example described for audio in WO 98/16014-A1 (PHN 16452), and for video in the MPEG2 standard. The input unit 27 processes the audio and/or video to units of information, which are passed to the formatter 28. The read processing unit 30 may comprise suitable audio and/or video decoding units.

The formatter 28 is for adding control data and formatting and encoding the data according to the recording format, e.g. by adding error correction codes (ECC), interleaving and channel coding. Further the formatter 28 comprises synchronizing means for including synchronizing patterns in the modulated signal. The formatted units comprise address information and are written to corresponding addressable locations on the record carrier under the control of control unit 20. The formatted data from the output of the formatter 28 is passed to the modulator 29, which generates a laser power control signal which drives the radiation source in the optical head. The formatted units presented to the input of the modulation unit 29 comprise address information and are written to corresponding addressable locations on the record carrier under the control of control unit 20.

The control unit 20 is arranged for controlling the recording by locating each block at a physical address in the track, and for performing defect management as described below. The control unit includes the following cooperating units: an addressing unit 31, a defect management unit 32, an assignment unit 34, and (optionally) a continuous data detection unit 33, which units are for example implemented in firmware.

The addressing unit 31 is for translating physical addresses into logical addresses and vice versa in dependence of defect management information. The logical addresses constitute a contiguous storage space to be used for storing sequences of information blocks, such as files under control of a file management system, for example UDF. The defect management unit 32 detects defects, for example by monitoring the signal quality of a read-out signal from the head 22 during recording and/or reading. The defects may also be detected by determining an error rate in retrieved information blocks. The defect management unit further maintains the defect management information in defect management areas on the record carrier, for example primary defect lists indicating slipped defects and secondary defect lists indicating remapped locations. The defect management information at least includes remapping information.

FIG. 3 shows remapping of defective locations. A physical address space 40 is schematically represented by a horizontal line. A series of blocks 42 is to be recorded in an allocated physical address range 39. However a defect 41 interrupts the allocated physical address range. Remapping 45 is the process that a block 44 having a logical address corresponding to the physical address 41 that is defective is stored in an alternative physical address in a defect management area (DMA) 43. The remapping information provides data for translating the logical address initially mapped to a physical address exhibiting a defect to an alternate physical address in a defect management area, for example an entry in a secondary defect list including the logical address of the remapped block and its corresponding physical address. Alternatively remapping information may include data for translation of a physical address of a defect to a different physical address in a defect management area.

The defect management areas are located on the record carrier according to a recording area layout. In the layout physical address are assigned a specific logical address of a user data area, or to a defect management area or system area, etc. The layout may be predefined, or may be defined according to parameters included in the system area. The defect management information includes assignment information indicative of assignment of physical addresses in first parts of the track to at least one user data area, and assignment of physical addresses in second parts of the track to defect management areas.

In an embodiment the assignment information includes assignment of specific defect management information to the defect management areas. The assignment of the defect management information to the defect management areas indicates the use of the defect management area, for example a primary defect list and a secondary defect list, or replacement area for a specific type of defects.

FIG. 4 shows a defect management layout having distributed defect management areas. A physical address space 40 is schematically represented by a horizontal line. First parts of the physical address space are assigned to user data areas 47,48, i.e. are assigned to logical addresses available for storing user data. Second parts of the physical address space are assigned to defect management areas 43,46, i.e. are not coupled to logical addresses. An example of a defect management layout is the Mount Rainier defect management for CD-MRW. A description of Mount Rainier and CD-MRW is available on http://www.licensing.philips.com/information/mtr/. In the logical space of the medium the DMAs are not visible. This means that if a large file is written to disc even if the entire file has continuous logical addresses, there will be DMAs included in the physical address allocated to the file.

Defect management areas are present on a medium for replacement purposes of defective locations. According to the invention the defect management layout is based on the actual nature and location of the defects on that specific disc. This means that in an area with a lot of defects, there are locally assigned more DMAs. The benefit is that the defect management areas are always close to the defects themselves, and in areas without defects there are no DMAs in between the user area. Due to the elimination of unused DMAs seek times for storing and readout of spare locations are minimized, or/and the trade off of “capacity foreseen for spare areas” and “capacity foreseen for user-data” can be optimized.

The function of the defect management areas is determined by the recording format and the recording area layout. The location of specific defect management areas is given in the assignment information, e.g. an assignment table giving the starting addresses of defect management areas. The size of each defect management area may be fixed, or may be included in the assignment information. The assignment unit 34 is for generating or adapting the assignment information in dependence of a detected defect. Initially only a limited amount, or even zero, defect management areas are actually assigned. Further, the assignment of physical address to logical addresses may be postponed until actual storage space is needed. During recording logical addresses are assigned as needed, and when a defect is detected, a new defect management area is created by assigning an additional physical address range to a new additional defect management area in said table. The additional physical address range is selected to start close to the detected defect, e.g. having a starting physical address near the detected defect. In particular the new defect management area may contain the erroneous location itself, in which case remapping is eliminated. The assignment of additional defect management areas is described with FIGS. 5 and 6. The dynamic assignment is in particular relevant for continuous data, which is to be reproduced at high speed, usually called streaming.

The continuous data detection unit 33 in FIG. 2 performs the following functions for detecting a logically continuous address range of blocks of information, in particular real-time data like digitally encoded video. A data type of recorded information is detected, in particular the type being streaming for real-time data like digitally encoded video, or non-streaming for random data like computer data files. The random access or streaming type of data can be detected in various ways, such as detecting the data type by monitoring commands for recording or retrieving information, retrieving record carrier information indicative of the data type, detecting a data type from the data structure of the recorded information. For example it is detected that a series of blocks having a continuous logical address range is to be recorded in a corresponding allocated physical address range. In general contiguous recording is required for real-time information which has a relative high data rate, in particular video information. The type of data may be included in the writing commands received by the control unit, for example a write command from a host computer including a real-time bit. The detection of contiguous recording may also be based on the amount of data blocks indicated in a write command, or by other aspects such as the fact that new blocks having logical addresses consecutive to the last written block arrive at regular intervals.

Typical drives don't have knowledge about files, e.g. start- and endpoints. A drive not having file-system knowledge can detect streaming write and retrieval behaviour as consequence of host activity based on read/write command information (streaming read and write commands) or when streaming indicators are stored on the disc, for example a “contiguous” bit included in a file entry (according to UDF in the file identifier descriptor) or a streaming bit included in a sector header, in zone-descriptors, or a streaming-location bitmap of the disc. Furthermore the use of the information in previous read or write sessions may be detected and stored for later use, e.g. by saving the nature of last activity (streaming/non-streaming) by the host on a specific location.

In an embodiment the device is provided with file-system knowledge and/or knowledge about the content recorded. Hence the data type can be retrieved directly from that knowledge. Alternatively file-system and content knowledge can be requested from the host system by interaction via the command interface with the drive.

It is noted that the function of the continuous data detection unit 33 and the assignment unit 34 can be performed as a separate defect management process independent of the moment of recording the information, for example in a computer program in a host computer controlling a disc drive. The drive accommodates the recording of information in blocks having logical addresses on the record carrier by locating each block at a physical address in the track, translating the logical addresses into the physical addresses and vice versa in dependence of defect management information, and detecting defects and maintaining the defect management information as described above. The defect management process comprises detecting a data type of recorded information, in particular the type being streaming for real-time data like digitally encoded video, or non-streaming for random data like computer data files, and changing the defect management information.

FIG. 5 shows dynamically assigning defect management areas. If a file contains multiple remapped blocks, it could happen that to retrieve such a file the drive has jump to various DMAs to get all the blocks. FIG. 5A shows a recorded file and remapped logical addresses in a conventional remapping system. A physical address space 40 is schematically represented by a horizontal line. A file 53 recorded in a logically continuous address range, which corresponds to a physical address range 60. The recording area layout defines distributed defect management areas 51,52. In the physical address range three errors 54,55,56 are detected. The first error 54 has been remapped to the first defect management area 51 as indicated by arrow 57, the second error 55 has been remapped to the second defect management area 52 as indicated by arrow 58, and the third error 56 has been remapped to the first defect management area 51 as indicated by arrow 59.

Retrieving the data in this example will cause three jumps back and forth to the two DMAs 51,52. These extra jumps will cause a considerable performance penalty when trying to maintain steaming behaviour from the host viewpoint. The solution is to assign defect management area on defects as they are discovered. It is noted that the new defect management area locations are unusable, but from a disc point of view the amount of usable User Space remains the same (because the defects would have to be remapped anyway). The DMAs are used in a new way. Instead of using predefined DMAs to place remapped data in, the DMAs are seen as a reserve pool of non-defective blocks; If a defect occurs in the user area, this is occupied by a DMA, thereby effectively exchanging user space with DMA space. This ensures that the total amount of user area on the disc remains constant despite the defects.

FIG. 5B shows an additionally assigned defect management area. The recorded data and defects from FIG. 5A are assumed. It is to be noted that no predefined defect management areas are present (the corresponding defect management areas 51,52 from FIG. 5A are absent). The first error 54 has been detected and an additional defect management area 61 has been assigned to the range of physical addresses starting with the location of the defect 54 itself. Because the physical address of defect location 54 is now no longer coupled to a logical address for user data, the first defect 54 does not need to be remapped. The logical address originally coupled to defect location 54 is now coupled to a new physical address, in particular to the physical address just after the defect management area 61. The second error 55 has now been remapped to the newly created defect management area 61 as indicated by arrow 62, and the third error 56 has also been remapped to the new defect management area 61 as indicated by arrow 63.

In an embodiment for large files certain parts of a continuous file are remapped to certain DMAs. Hence a first logical address range within the continuous data file is remapped to a first newly created defect management area, while a second (non overlapping, e.g. contiguous) logical address range within the continuous data file is remapped to a second newly created defect management area. The DMAs can be retrieved consecutively during reproducing the respective consecutive logical address ranges.

A new DMA may be created in dependence of several defect management parameters, such as the distance to the previous DMA, the amount of space left in the previous DMA, the size of part of the continuous file intermediate between the current defect and the DMA, etc. In addition, the size of a DMA may be predefined, or may be based on defect parameters of a preceding or following recording area, in particular the amount and distribution of defect management areas already assigned, the amount of user area between the additional physical address range and a preceding or following defect management area, and/or the amount or density of detected defects.

FIG. 5C shows delayed assignment of a defect management area. The recorded data and defects from FIG. 5A are assumed, without pre-assigned defect management areas 51,52. The first error 54 and second defect 55 have been detected, but selecting a corresponding remapping location has been postponed. At the third defect 56 an additional defect management area 66 has been assigned to the range of physical addresses starting with the location of the defect 56 itself. Because the physical address of the third defect location 56 is now no longer coupled to a logical address for user data, the defect 56 does not need to be remapped. The logical address originally coupled to defect location 56 is now coupled to a new physical address, in particular to the physical address just after the defect management area 66. The first error 54 has now been remapped to the newly created defect management area 66 as indicated by arrow 64, and the second error 55 has also been remapped to the new defect management area 66 as indicated by arrow 65. Delaying the creation of a new defect management area is made dependent on parameters such as the distance to the previous DMA, the amount of space left in the previous DMA, the amount of defects since the previous DMA, etc.

FIG. 5D shows a defect management area assigned covering two defects. The recorded data and defects from FIG. 5A are assumed, without pre-assigned defect management areas 51,52. The first error 54 and second defect 55 have been detected, and an enlarged defect management area 67 has been assigned covering both defects and the intermediate physical addresses (and intermediate defects, if any). Obviously, if more defects are detected near the first two, a larger size defect management area covering the group may be assigned. Hence the size of the defect management area 67 is made dependent on detected defects to be covered. In the example the third error 56 has been remapped to the newly created defect management area 67 as indicated by arrow 68. The creation of the enlarged type of defect management area is made dependent on parameters such as the density of defects, or the size of the flawed area having an increased defect rate.

FIG. 6 shows assigning ranges of physical address to a defect management area. FIG. 6A shows assigned physical addresses and remapped defects in a conventional remapping system. A physical address space 40 is schematically represented by a horizontal line. A file 53 recorded in a logically continuous address range. The recording area layout defines a defect management area 52. In the physical address range an error 70 is detected. The error 70 has been remapped to the (remote) defect management area 52 as indicated by arrow 71.

FIG. 6B shows assigning an additional physical address range to an additional defect management area. The recorded data and defects from FIG. 6A are assumed. After detecting the error 70 a new defect management area 72 is created at the end of the continuous address range for recording the user data file. After the file 53 a free space 75 is assumed. For example the drive may keep track of recorded areas of the record carrier, or the control unit can search for the first free block and put a DMA location there. The last option requires file system knowledge in the drive or close communication with the file system in the application. The error 70 has been remapped to the newly created defect management area 72 as indicated by arrow 74. Hence the jumping distance during recording and read-out for recovering the remapped logical address is reduced.

In an embodiment the pre-assigned defect management area 52 has been reduced to a new and smaller defect management area 73. By reducing the size with a same amount as the newly created defect management area 72 the total amount of user space and defect management space remains constant.

It is to be noted that adding a DMA to the defect management information automatically results in an adapted translation of logical addresses to physical addresses after the new DMA. Various options are available for accommodating the new mapping of logical addresses in the user data area when an additional DMA is assigned. Only when user data has already been recorded at a logical address beyond the additional DMA this data needs to be shifted, or the file management data needs to be adapted to the new logical addresses. Alternatively offset tables can be maintained for calculating the logical addresses.

In an embodiment a predetermined ratio for defect management space and user data space is specified in the recording format, e.g. in the defect management information. When recording has to be started at a new logical address the physical size and ratio of the preceding recording area are fixed by setting a mapping of the new starting logical address to a physical address past the fixed area. A mapping table for such areas may be included in the defect management information.

In an embodiment the recording area is subdivided in zones each having a fixed logical starting address. Each zone may have a fixed amount of defect management space available, which can be assigned to physical addresses during use of that zone.

It is noted that by removing (part of) a DMA from the available total defect management space is a possibility to create some free space (for the drive system data or user data) at a desired location at a medium. If the space has to be accessible for the user updating of the logical address space is required.

Although the invention has been explained mainly by embodiments using the CD, similar embodiments like DVD or BD having defect management can apply the invention. Also for the information carrier an optical disc has been described, but other media such as a magnetic hard disc can be used. It is noted, that in this document the word ‘comprising’ does not exclude the presence of other elements or steps than those listed and the word ‘a’ or ‘an’ preceding an element does not exclude the presence of a plurality of such elements, that any reference signs do not limit the scope of the claims, that the invention may be implemented by means of both hardware and software, and that several ‘means’ may be represented by the same item of hardware. Further, the scope of the invention is not limited to the embodiments, and the invention lies in each and every novel feature or combination of features described above.

1. Device for recording information in blocks having logical addresses, which device comprises
recording means (22) for recording marks in a track on a record carrier representing the information,
control means (20) for controlling the recording by locating each block at a physical address in the track, the control means comprising
addressing means (31) for translating the logical addresses into the physical addresses and vice versa in dependence of defect management information,
defect management means (32) for detecting defects and maintaining the defect management information in defect management areas on the record carrier,
the defect management information including assignment information indicative of assignment of physical addresses in first parts of the track to at least one user data area, and assignment of physical addresses in second parts of the track to defect management areas, and the defect management information including remapping information indicative for translating a logical address initially mapped to a physical address exhibiting a defect to an alternate physical address in a defect management area, and
assignment means (34) for adapting the assignment information in dependence of a detected defect by assigning an additional physical address range to an additional defect management area, the additional physical address range having a starting physical address near the detected defect.

2. Device as claimed in claim 1, wherein the assignment means (34) are for assigning the additional physical address range including the detected defect.

3. Device as claimed in claim 1, wherein the assignment means (34) are for assigning the additional physical address range having a predefined size, or a size based on defect parameters of a preceding or following recording area, in particular the amount and distribution of defect management areas already assigned, the amount of user area between the additional physical address range and a preceding or following defect management area, and/or detected defects.

4. Device as claimed in claim 1, wherein the assignment means (34) are for assigning the additional physical address range having a size including at least a first detected defect, a second detected defect and the physical addresses between the first and second detected defect.

5. Device as claimed in claim 1, wherein the assignment means (34) are for assigning the additional physical address range to a range of physical address in a part of the track originally assigned to the at least one user data area, in particular the part of the track being a free space in the user data area.

6. Device as claimed in claim 1, wherein the device comprises contiguous recording detection means (33) for detecting a series of blocks having a continuous logical address range to be recorded in a corresponding allocated physical address range, and
the assignment means (34) are for assigning the additional physical address range outside the allocated physical address range.

7. Device as claimed in claim 6, wherein the contiguous recording detection means (33) are for detecting a continuous recordings indicator in a recording command, or for detecting the series of blocks representing real-time information, in particular video information, or for detecting file system information for detecting that the series of blocks constitute a file.

8. Method of recording of information in blocks having logical addresses located at a physical address in a track on a record carrier,
the logical addresses corresponding to physical addresses in dependence of defect management information,
defects being detected and the defect management information being maintained in defect management areas on the record carrier, and
the defect management information including assignment information indicative of assignment of physical addresses in first parts of the track to at least one user data area, and assignment of physical addresses in second parts of the track to defect management areas, and the defect management information including remapping information indicative for translating a logical address initially mapped to a physical address exhibiting a defect to an alternate physical address in a defect management area,
the method comprising
adapting the assignment information in dependence of a detected defect by assigning an additional physical address range to an additional defect management area, the additional physical address range having a starting physical address near the detected defect.

9. Computer program product for recording of information, which program is operative to cause a processor to perform the method as claimed in claim 8.
